(19) United States
(12) Patent Application Publication
(10) Pub. No.: US 2025/0189608 A1
(43) Pub. Date: Jun. 12, 2025

(54) CRYOGENIC PROBE AND MAGNETIC RESONANCE IMAGING SYSTEM

(71) Applicant: WUHAN UNITED IMAGING LIFE SCIENCE INSTRUMENT CO., LTD, Wuhan (CN)

(72) Inventors: Chuo Xie, Wuhan (CN); Qi Wu, Wuhan (CN)

(21) Appl. No.: 18/971,113

(22) Filed: Dec. 6, 2024

(30) Foreign Application Priority Data
Dec. 6, 2023 (CN) 202311681177.8

(51) Int. Cl. G01R 33/34

(52) U.S. Cl. CPC G01R 33/34007; G01R 33/3403

(57) ABSTRACT

A cryogenic probe and a magnetic resonance imaging system are provided. The cryogenic probe includes a housing, at least one coil, and a cooling conductive structure. The at least one coil is disposed in the housing. The cooling conductive structure is disposed in the housing and is provided with at least one coil groove, and the at least one coil is at least partially accommodated in the at least one coil groove.

### CROSS-REFERENCE TO RELATED APPLICATION

This application claims priority to Chinese patent application No. 202311681177.8, filed on Dec. 6, 2023, titled “CRYOGENIC PROBE AND MAGNETIC RESONANCE IMAGING SYSTEM”, the content of which is hereby incorporated by reference in its entirety.

### TECHNICAL FIELD

The present disclosure generally relates to the field of pre-clinical and scientific research applications, and in particular, to a cryogenic probe and a magnetic resonance imaging system.

### BACKGROUND

A radio frequency coil is configured to transmit a radio frequency pulse and/or receive an MR (magnetic resonance) signal. As a front end of a signal receiving chain, the radio frequency coil is important for imaging quality, and is a core member of a magnetic resonance (Nuclear magnetic resonance) imaging system.

Compared with a common normal-temperature radio frequency coil, a cryogenic radio frequency coil has a higher SNR (signal-to-noise ratio), a higher sensitivity, a faster detection speed, and a corresponding better imaging quality. The key to realize the cryogenic radio frequency coil is how to efficiently refrigerate a radio frequency coil in a cryogenic probe.

In the related art, a cryogenic radio frequency coil has a complex refrigerating structure or has a high requirement for a manufacturing process, and cannot be actually applied in an industry. In addition, a flexible plate may be compressed into a cooling conductive structure via a structural member. However, this solution results in that a cooling conductive effect between the cooling conductive structure and the coil is poor, thereby decreasing the SNR, and a use requirement cannot be met.

### SUMMARY

According to various embodiments of the present disclosure, a cryogenic probe and a magnetic resonance imaging system are provided.

In a first aspect, a cryogenic probe is provided. The cryogenic probe includes a housing, at least one coil, and a cooling conductive structure. The at least one coil is disposed in the housing. The cooling conductive structure is disposed in the housing and is provided with at least one coil groove, and the at least one coil is at least partially accommodated in the at least one coil groove.

In an embodiment, the at least one coil groove is disposed on a side surface of the cooling conductive structure proximal to a to-be-tested target. Any one of the at least one coil includes a coil conductor and a radio frequency element, the coil conductor is at least partially accommodated in one of the at least one coil groove, a gap exists between the cooling conductive structure and an inner wall of the housing, and a gap exists between the coil conductor and the inner wall of the housing.

In an embodiment, the side surface of the cooling conductive structure proximal to the to-be-tested target is an arc surface, and the coil conductor is at least partially accommodated in the one of the at least one coil groove along a radial direction of the arc surface.

In an embodiment, the coil conductor protrudes at least in part from the arc surface along the radial direction of the arc surface.

In an embodiment, the coil conductor has a circular cross-section, and a depth of the at least one coil groove is less than or equal to a size of the coil conductor along a depth direction of the at least one coil groove.

In an embodiment, an interior of the housing is a vacuum environment, and a gap between the coil conductor and the inner wall of the housing proximal to the to-be-tested target is less than or equal to 1.0 mm.

In an embodiment, the cooling conductive structure is further provided with a through hole in communication with the at least one coil groove, and the coil conductor is electrically connected to the radio frequency element through the through hole.

In an embodiment, the cryogenic probe includes at least two coils, parts of adjacent coil conductors overlap with each other, and one of the adjacent coil conductors at an overlapping position prevents collisions with the other coil conductor of the adjacent coil conductors on a side away from the to-be-tested target.

In an embodiment, the at least one coil groove is filled with either or both of cooling conductive grease and cooling conductive gel, and either or both of cooling conductive grease and cooling conductive gel are in contact with both the coil conductor and an inner wall of the at least one coil groove.

In an embodiment, the at least one coil groove is filled with cooling conductive gel, and the cooling conductive gel is arranged at intervals along an extension direction of the coil conductor.

In an embodiment, the cryogenic probe further includes a cryogenic platform, and the cooling conductive structure is capable of performing heat exchange with the cryogenic platform.

In a second aspect, a magnetic resonance imaging system is further provided. The magnetic resonance imaging system includes the above cryogenic probe and a magnetic resonance device, the magnetic resonance device includes a magnet with a scanning cavity, and the cryogenic probe is capable of entering the scanning cavity.

### BRIEF DESCRIPTION OF THE DRAWINGS

In order to more clearly illustrate the technical solutions in the embodiments of the present disclosure or the related technology, the accompanying drawings to be used in the description of the embodiments or the related technology will be briefly introduced below, and it will be obvious that the accompanying drawings in the following description are only some of the embodiments of the present disclosure, and that, for one skilled in the art, other accompanying drawings can be obtained based on these accompanying drawings without putting in creative labor.

FIG. 1 is a schematic cross-sectional diagram of a cryogenic probe in the present disclosure.

FIG. 2 is a schematic diagram of a three-dimensional structure of a coil of FIG. 1.

FIG. 3 is a schematic cross-sectional diagram of a cooling conductive structure and a coil of FIG. 1.

FIG. 4 is a schematic bottom diagram of a cooling conductive structure and a coil of FIG. 1.

FIG. 5 is a schematic cross-sectional diagram of a cooling conductive structure of FIG. 1.

FIG. 6 is a schematic diagram of a cryogenic platform in the present disclosure.

FIG. 7 is a schematic diagram of a magnetic resonance imaging system in the present disclosure.

In the figures, 10 represents a housing, 20 represents a coil, 21 represents a coil conductor, 22 represents a radio frequency element, 30 represents a cooling conductive structure, 31 represents a coil groove, 32 represents a through hole, 33 represents a clamping slot, 41 represents a magnet, and 42 represents a scanning cavity.

### DETAILED DESCRIPTION OF THE EMBODIMENT

The technical solutions in the embodiments of the present disclosure will be described clearly and completely in the following in conjunction with the accompanying drawings in the embodiments of the present disclosure, and it is obvious that the described embodiments are only a part of the embodiments of the present disclosure, but not all of the embodiments. Based on the embodiments in the present disclosure, all other embodiments obtained by one skilled in the art without making creative labor fall within the scope of protection of the present disclosure.

In the description of the present disclosure, it should be understood that a location or a position relationship indicated by terms such as “center”, “longitudinal”, “lateral”, “length”, “width”, “thickness”, “upper”, “lower”, “front”, “back”, “left”, “right”, “vertical”, “horizontal”, “top”, “bottom”, “inside”, “outside”, “clockwise”, “counter-clockwise”, “axial”, “radial”, “circumferential” is based on a location or a position relationship shown in the accompanying drawings, merely for ease of description and simplification of the present disclosure, and is not intended to indicate or imply that a pointing apparatus or an element must have a specific orientation, be constructed and operated in a specific orientation. Therefore, the present disclosure is not limited thereto.

In addition, terms “first” and “second” are used only for a purpose of description, and cannot be understood to indicate or imply relative importance or implicitly indicate the number of indicated technical features. Therefore, a feature defined with “first” or “second” may explicitly or implicitly include at least one feature. In the description of the present disclosure, “multiple” means at least two, for example, two, three, and so on, unless otherwise specifically limited.

In the present disclosure, unless otherwise specified and limited, terms such as “mount”, “coupling”, “connect”, and “fix” should be understood broadly. For example, a term may be a fixed connection, may be a detachable connection, or may be integrally formed. A term may be a mechanical connection, or may be an electrical connection. A term may be directly connected, or may be indirectly connected by an intermediate medium. A term may be an internal communication between two elements, or an interaction relationship between the two elements, unless otherwise specifically limited. One skilled in the art may understand a specific meaning of the foregoing terms in the present disclosure according to a specific situation.

In the present disclosure, unless otherwise specified and limited, a first feature is “on” or “under” a second feature, which means that the first feature is in direct contact with the second feature, or the first feature is in indirect contact with the second feature by an intermediate medium. In addition, the first feature is “on”, “above”, or “over” the second feature, which means that the first feature is directly above or obliquely above to the second feature, or indicates that a height of the first feature is greater than that of the second feature. The first feature is “under” or “below” the second feature, or “lower” than the second feature, which means that the first feature is directly below or obliquely below the second feature, or indicates that the height of the first feature is less than that of the second feature.

It should be noted that when an element is considered to be “fixed” or “disposed” to another element, it may be directly on another element, or there may be a centered element. When one element is considered to be “connected” to another element, it may be connected directly to another element, or there may be a centered element at the same time. The terms “vertical”, “horizontal”, “upper”, “lower”, “left”, “right” and similar expressions used herein are for illustrative purposes and are not intended to represent the only implementation.

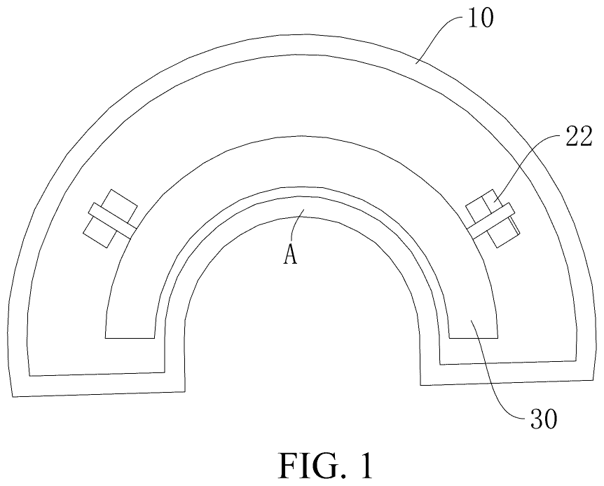

Referring to FIG. 1 to FIG. 4, a cryogenic probe is provided in the present disclosure. The cryogenic probe includes a housing 10, at least one coil 20, and a cooling conductive structure. The cooling conductive structure 30 is disposed in the housing 10 and is provided with at least one coil groove 31, and the at least one coil 20 is at least partially accommodated in the at least one coil groove 31.

For ease of description, the coil 20 in the specification may refer to a radio frequency coil, and be configured to transmit a radio frequency pulse and/or receive an MR signal.

In some embodiments, the cryogenic probe may further include a cryogenic platform, and the cooling conductive structure is capable of performing heat exchange with the cryogenic platform.

The cryogenic platform may provide cooling and transfer the cooling to the cooling conductive structure 30 via the heat exchange, so as to ensure that the cooling conductive structure 30 is in an ultra-cryogenic state, and a temperature of the cooling conductive structure 30 may be 30K or lower. Therefore, the cooling conductive structure 30 may be used as a relay to implement heat exchange via contact between the cooling conductive structure 30 and the coil 20, so as to implement refrigeration of the coil 20, thereby reducing thermal noise of the coil 20, improving sensitivity of the coil 20, and improving imaging quality.

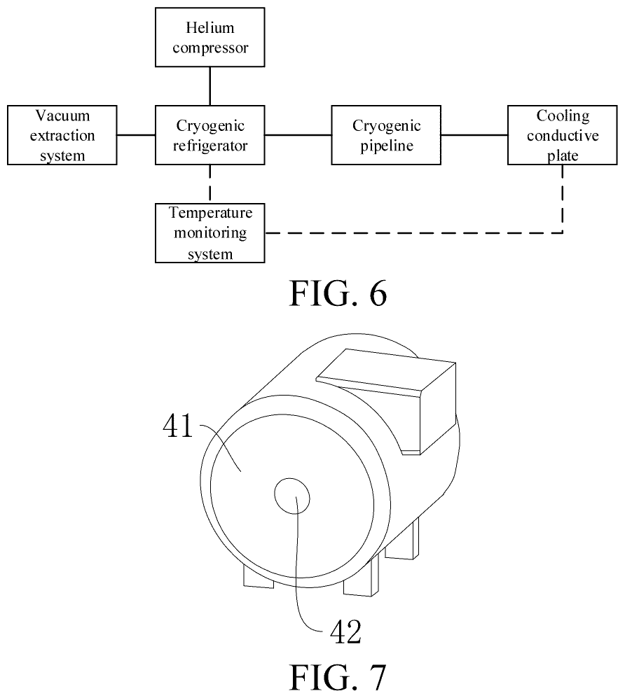

Specifically, referring to FIG. 6, the cryogenic platform may include a cryogenic refrigerator, a helium compressor, a vacuum extraction system, a cryogenic pipeline, and a temperature monitoring system. The cryogenic refrigerator is connected to the helium compressor and the vacuum extraction system, respectively, and the cryogenic refrigerator is further connected to the cooling conductive structure 30 by the cryogenic pipe. The temperature monitoring system may monitor a temperature of the cryogenic refrigerator and a temperature of the cooling conductive structure 30, respectively. The cryogenic platform can provide cooling via cryogenic helium gas.

Specifically, the heat exchange between the cryogenic platform and the cooling conductive structure 30 may be implemented via a common heat exchange form, for example, via a contact or a cooling cycle pipeline, as long as the cooling conductive structure 30 is cooled to the ultra-cryogenic state by cooling provided by the cryogenic platform, which is not further limited in the present disclosure.

In the present disclosure, the cooling conductive structure 30 is provided with the at least one coil groove 31, and the at least one coil 20 is at least partially accommodated in the at least one coil groove 31. Compared with the related solution, i.e., a cryogenic radio frequency coil is compressed into a cooling conductive structure, in the present disclosure, a contact area between the coil 20 and the cooling conductive structure is larger, and a heat exchange capability between the cooling conductive structure 30 and the coil 20 may be effectively improved. Therefore, the refrigeration of the coil 20 may be efficiently completed, the thermal noise of the coil 20 may be reduced, and a signal-to-noise ratio of the coil 20 may be improved.

In addition, in the present disclosure, the cooling conductive structure 30 and the coil 20 may be disposed inside the housing 10, and a cryogenic part may be separated from a to-be-tested target via the housing 10, so that a temperature of the housing 10 may approach a normal temperature, thereby reducing a frostbite possibility of the to-be-tested target. In some embodiments, the housing 10 may be made of a ceramic material including aluminum nitride, in particular an AlN (aluminum nitride) ceramic material including BN (boron nitride). These materials may be made into any shape, including hollow and concave surfaces. In the present embodiment, the housing 10 may be a hollow housing. The cooling conductive structure 30 may include a cooling conductive plate, a cooling conductive board, or other suitable structure. The quantity of the at least one coil groove may be the same as that of the at least one coil, or the quantity of the at least one coil groove may be different from that of the at least one coil.

In some embodiments, the housing may include a heat insulation portion which is integrally formed. The heat insulation portion is capable of reducing cooling transferred from the inside of the housing 10 to an outside surface of the housing 10, and further reducing a frostbite possibility of the to-be-tested target. In some embodiments, the heat insulation portion may be a vacuum portion proximal to an inner wall A of the housing 10. Referring to FIG. 1 to FIG. 4, in some embodiments, the coil groove 31 may be disposed on a side surface B of the cooling conductive structure 30 proximal to the to-be-tested target. The coil 20 may include a coil conductor 21 and a radio frequency element 22. The radio frequency element 22 is configured to transmit the radio frequency pulse and/or receive the MR signal. The coil conductor 21 may be at least partially accommodated in the coil groove 31, and a gap may exist between the coil conductor 21 and the inner wall A of the housing 10 that is proximal to the to-be-tested target.

It may be understood that the less a distance between the coil conductor 21 and the to-be-tested target is, the better the signal-to-noise ratio of the coil 20 is. The coil groove 31 may be disposed on the side surface B of the cooling conductive structure 30 proximal to the to-be-tested target, which may ensure that the distance between the coil conductor 21 and the to-be-tested target is relatively less after the coil conductor 21 is inserted into the coil groove 31, so as to improve the signal-to-noise ratio of the coil.

In addition, when either of the coil conductor 21 and the cooling conductive structure 30 is in direct contact with the housing 10, the cooling of the coil conductor 21 and the cooling conductive structure 30 may be transmitted to the housing 10, thereby causing the temperature of the housing 10 to be too low and a risk of frostbite of the to-be-tested target. The coil conductor 21 and the cooling conductive structure 30 may be disposed at intervals with the housing 10, respectively, so that a gap may exist between the coil conductor 21 and the housing 10, and a gap may exist between the cooling conductive structure 30 and the housing 10. It may be avoided that the coil conductor 21 and the cooling conductive structure 30 are in contact with the housing 10, thereby effectively reducing heat conducting efficiency between the coil conductor 21 and the housing 10, and between the cooling conductive structure 30 and the housing 10, and reducing a risk of frostbite.

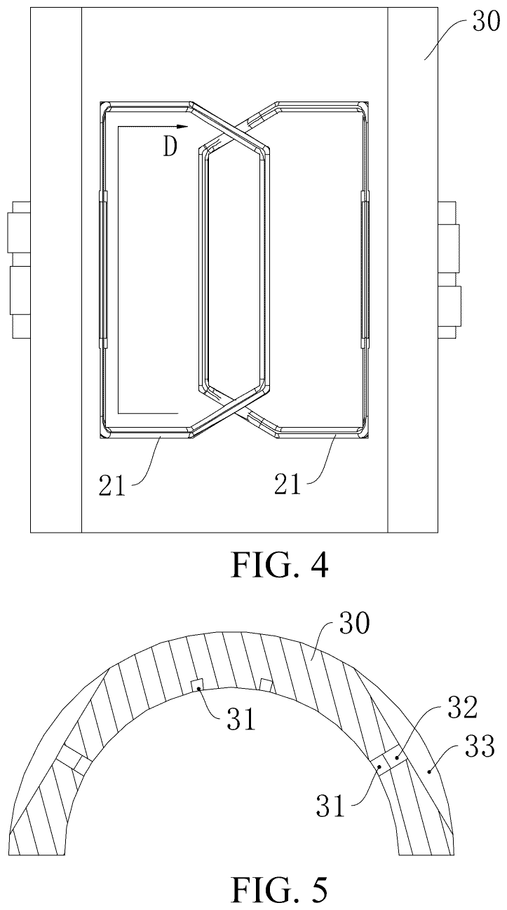

In some embodiments, the side surface B of the cooling conductive structure 30 proximal to the to-be-tested target may be an arc surface, and the coil conductor 21 may be at least partially accommodated in the coil groove 31 along an extending direction of the coil conductor 21 and/or a radial direction of the arc surface. The extending direction of the coil conductor 21 may be a direction D shown in FIG. 4. The coil conductor 21 may also be at least partially accommodated in the coil groove 31 along other directions, which is not limited herein.

In some embodiments, the coil conductor 21 may be at least partially accommodated in the coil groove 31 and protrude at least in part from the arc surface along the radial direction of the arc surface.

While the coil conductor 21 is accommodated and a contact area between the coil conductor 21 and the cooling conductive structure 30 is increased, the distance between the coil conductor 21 and the to-be-tested target may be reduced, and the signal-to-noise ratio of the coil may be further improved. In addition, it may be further ensured that a clear gap is maintained between the cooling conductive structure 30 and the inner wall A of the housing 10, so as to avoid a case that the cooling of the cooling conductive structure 30 is directly transmitted to the housing 10, resulting from that the cooling conductive structure 30 is in incorrect contact with the housing 10 due to shaking or other external force factor.

Alternatively, a proportion of an area of the part of the coil conductor 21 that protrudes from the arc surface to a cross-sectional area of the coil conductor 21 may be less than or equal to one half. Therefore, the distance between the coil conductor 21 and the to-be-tested target may be reduced, and the coil conductor 21 may not protrude from the arc surface too much.

In some embodiments, the coil conductor 21 may protrude at least in part from the arc surface along the radial direction of the arc surface, and a depth of the coil groove 31 may be less than or equal to a size of the coil conductor 21 along a depth direction of the coil groove 31. The coil conductor 21 may increase cooling transmission efficiency by decreasing a distance between a bottom wall of the coil groove 31 and the coil conductor 21. The depth direction of the coil groove 31 may be denoted as h in FIG. 3. In some embodiments, the depth direction of the coil groove 31 may be the radial direction of the arc surface.

Alternatively, the bottom wall of the coil groove 31 may be bonded to the coil conductor 21, so as to increase a contact area between the cooling conductive structure 30 and the coil conductor 21 as much as possible, and increase cooling transmission efficiency.

In some embodiments, the coil groove 31 may have a partially circular cross-section, the coil conductor 21 may be at least partially accommodated in the coil groove 31 along the radial direction of the arc surface, and the coil conductor 21 may be bonded to an inner wall C of the coil groove 31. The partially circular cross-section means that an edge of the coil groove 31 is in a shape of arc, so that a clamping structure may be defined by the coil groove 31.

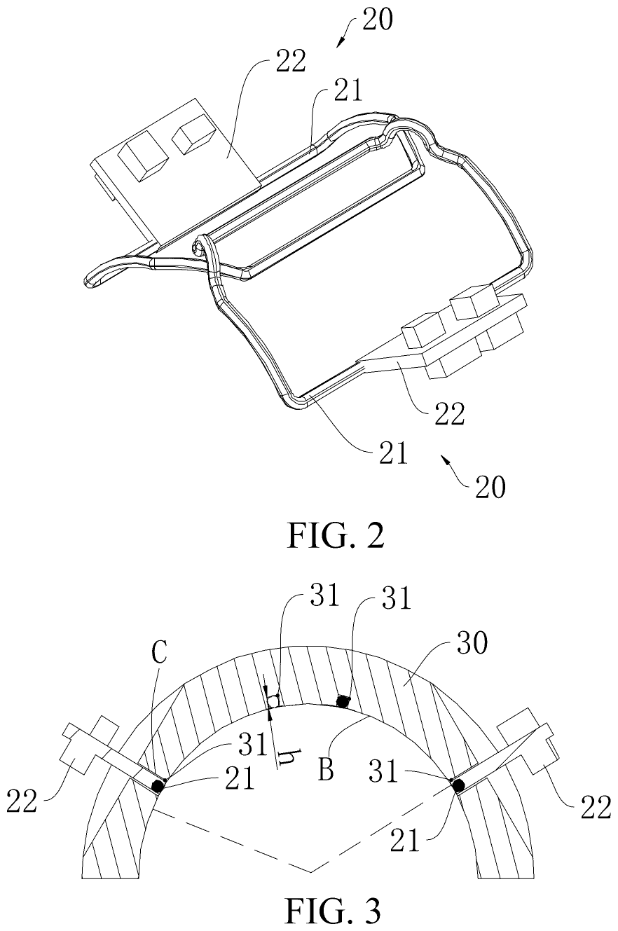

The coil 20 and the cooling conductive structure 30 may also be in other shapes, for example, the coil 20 and the cooling conductive structure 30 may be both rectangular, and the like, as long as the coil conductor 21 can be shaped and bonded to the inner wall C of the coil groove 31 to obtain a large contact area, which is not further limited herein. Referring to FIG. 2 to FIG. 4, in some embodiments, the depth of the coil groove 31 may be equal to the size of the coil conductor 21 along the depth direction of the coil groove 31, and the coil conductor 21 may be accommodated in the coil groove 31 completely. In some embodiments, a cross-section of the coil conductor 21 may be in a shape of circle, a diameter of the cross-section of the coil conductor 21 may be 0.5 mm. The depth direction of the coil groove 31 may be denoted as h in FIG. 3. In some embodiments, the depth direction of the coil groove 31 may be the radial direction of the arc surface. The size of the coil conductor 21 along a depth direction of the coil groove 31 may be a size of the coil conductor 21 along the radial direction of the arc surface.

The more the coil conductor 21 is accommodated in the coil groove 31, the stronger a heat conducting capability between the coil conductor 21 and the coil groove 31, and the better the cooling effect on the coil 20. Therefore, by accommodating the coil conductor 21 in the coil groove 31 completely, the cooling effect of the cooling conductive structure 30 on the coil 20 may be maximized, thereby reducing the thermal noise of the coil 20, improving sensitivity of the coil 20, improving a detecting speed, and improving imaging quality.

Referring to FIG. 2 to FIG. 4, in some embodiments, an interior of the housing 10 may be a vacuum environment, and a gap between the coil conductor 21 and the inner wall A of the housing 10 proximal to the to-be-tested target may be less than or equal to 1.0 mm.

Since heat conduction is mainly performed via air or an object as a medium, heat conduction between the housing 10 and the cooling conductive structure 30, and between the housing 10 and the coil 20 may be blocked by performing vacuum inside the housing 10. On this basis, a position of the coil conductor 21 may be as proximal as possible to the inner wall A of the housing 10, so as to minimize a distance between the coil conductor 21 and the to-be-tested target. It is not necessary to consider whether the coil conductor 21 is too proximal to the housing 10 to cause that a temperature of the housing 10 is too low to frostbite the to-be-tested target, so that a distance between the coil conductor 21 and the to-be-tested target may be reduced as much as possible while ensuring safety of the to-be-tested target, thereby improving a signal-to-noise ratio of the coil 20.

In the present disclosure, the gap between the coil conductor 21 and the inner wall A of the housing 10 proximal to the to-be-tested target may be set to be less than or equal to 1.0 mm, so as to ensure a relatively short distance between the coil conductor 21 and the to-be-tested target, and obtain a relatively high signal-to-noise ratio.

In some embodiments, the gap between the coil conductor 21 and the inner wall A of the housing 10 proximal to the to-be-tested target may be less than or equal to 0.8 mm, 0.9 mm, 1.1 mm, 1.2 mm, or the like.

By calculation, simulation, and test verification, when the distance between the coil conductor 21 and the inner wall A of the housing 10 is controlled within the foregoing range, the signal-to-noise ratio of the coil 20 may meet a practical use requirement.

Furthermore, in some embodiments, the bottom wall of the coil groove 31 may be tangent to the coil conductor 21. It may be understood that efficiency of performing heat exchange between the coil conductor 21 and the bottom wall of the coil groove 31 by contact is far higher than efficiency of heat conduction in a case of no contact. Therefore, a cooling effect and the signal-to-noise ratio of the coil 20 may be further improved in the above way.

In conclusion, in the present disclosure, multiple factors such as a groove depth of the coil groove 31, a relative position relationship between the coil conductor 21 and the cooling conductive structure 30, an internal environment of the housing 10, and a gap range between the coil conductor 21 and the housing 10 may be comprehensively designed, so that performance of the cryogenic probe in the present disclosure is excellent in terms of an imaging effect, a refrigeration effect on the coil 20, and use safety (risk of frostbite of the to-be-tested target).

In some embodiments, the side surface B of the cooling conductive structure 30 proximal to the to-be-tested target may be an arc surface, and the coil conductor 21 may be at least partially accommodated in the coil groove 31 along a radial direction of the arc surface.

In some embodiments, a size of a part of the coil conductor 21 protruding from the cooling conductive structure 30 and proximal to the to-be-tested target may be less than or equal to half of a diameter of the coil conductor 21, so as to ensure a sufficiently large contact area between the coil conductor 21 and the cooling conductive structure 30. A cooling transmission capability between the coil conductor 21 and the cooling conductive structure 30 may satisfy a requirement, thereby reducing thermal noise of the coil 20 and improving the signal-to-noise ratio of the coil 20.

Referring to FIG. 5, in some embodiments, a side surface of the cooling conductive structure 30 away from the to-be-tested target may be provided with a through hole 32 in communication with the coil groove 31. A radio frequency element 22 may extend through the through hole 32 to protrude from the side surface of the cooling conductive structure 30 away from the to-be-tested target, and the coil conductor 21 may be electrically connected to the radio frequency element 22 through the through hole 32.

Furthermore, the coil conductor 21 may be electrically connected to the radio frequency element 22 by a conductive medium disposed in the through hole 32.

In a practical mounting process, the coil conductor 21 may be first mounted in the coil groove 31, and then the radio frequency element 22 may be electrically connected to the coil conductor 21 via the conductive medium, so as to complete mounting process between the coil 20 and the cooling conductive structure 30.

In some embodiments, the side surface of the cooling conductive structure 30 away from the to-be-tested target may be provided with a clamping slot 33 in communication with the through hole 32. It may be understood that, to ensure normal mounting of the radio frequency element 22, a gap must exist between the radio frequency element 22 and the through hole 32, and the radio frequency element 22 and the through hole 32 cannot be fully attached to each other. On the one hand, the clamping slot 33 is configured to clamp and fix the radio frequency element 22 after the coil 20 is mounted, so as to prevent the radio frequency element 22 from moving relative to the cooling conductive structure 30. On the other hand, the clamping slot 33 may be disposed to reduce a depth of the through hole 32, so that the coil conductor 21 may be welded to the radio frequency element 22 through the through hole 32 in a welding process, thereby reducing welding difficulty between the radio frequency element 22 and the coil conductor 21.

In some embodiments, an extension direction of the coil groove 31 may be the same as an arranging direction of the coil conductor 21, i.e., the coil groove 31 and the coil conductor 21 may be designed in a similar manner, so that a gap between the coil conductor 21 and the coil groove 31 may be reduced as much as possible, and a cooling transmission capability between the cooling conductive structure 30 and the coil conductor 21 may be increased. Referring to FIG. 4, an extension direction of each position of the coil groove 31 may be the same as an extension direction D of a corresponding position of the coil conductor 21. The extension direction of each position of the coil groove 31 may be perpendicular to the radial direction of the arc surface.

Referring to FIG. 2, in some embodiments, the cryogenic probe may include at least two coils 20, each of the at least two coils may include a coil conductor 21, parts of adjacent coil conductors 21 may overlap with each other, and one of the adjacent coil conductors 21 at an overlapping position may prevent collisions with the other coil conductor 21 of the adjacent coil conductors 21 on a side away from the to-be-tested target.

In a case of multiple coils 20, partial overlapping between adjacent coils 20 may be a common arrangement manner, which can improve the signal-to-noise ratio. The “prevent collisions” mentioned herein may refer to that one of the coil conductors 21 is bent at the overlapping position towards the side away from the to-be-tested target to form a bridge or another structure, so as to avoid mutual interference caused by contact between adjacent coil conductors 21 at the overlapping position, while ensuring that other parts of the coil conductors 21 are unchanged in shape.

It may be understood that when the coil conductor 21 is bent to a side proximal to the to-be-tested target, a distance between a bent part of the coil conductor 21 and the inner wall of A the housing 10 may be decreased, even the bent part of the coil conductor 21 may protrude from the coil groove 31, so that the cooling may be transmitted to the housing 10 via the bent part of the coil conductor 21, which affects the cooling effect of the coil 20 and has a risk of frostbite of the to-be-tested target.

When the entire coil conductor 21 is moved away from the to-be-tested target, so as to ensure that a distance between the bent part of the coil conductor 21 and the housing 10 is within a proper range, the distance between the coil conductor 21 and the to-be-tested target may be increased, and the signal-to-noise ratio of the coil 20 may be reduced.

In the present disclosure, the coil conductor 21 may be bent to the side away from the to-be-tested target, and a distance between the entire coil 20 and the housing 10 may not be increased, so that the cooling effect of the coil 20 may not be affected or the risk of frostbite may not exist. In addition, the distance between parts of coil conductors 21 at the overlapping position and the to-be-tested target may be increased, and the distance between the other parts of coil conductors 21 and the to-be-tested target may remain unchanged. Therefore, the signal-to-noise ratio of the entire coil 20 may be affected less.

Furthermore, in some embodiments, the coil groove 31 may be deeper at the overlapping position of the coil 20 than other positions, so as to accommodate the bent part of the coil conductor 21.

In some embodiments, the coil groove 31 may be filled with either or both of cooling conductive grease and cooling conductive gel, and either or both of cooling conductive grease and cooling conductive gel may be in contact with both the coil conductor 21 and the inner wall C of the coil groove 31. The cooling conductive grease and/or the cooling conductive gel may increase a contact area between the coil conductor 21 and the coil groove 31, thereby further improving a heat conducting capability between the cooling conductive structure 30 and the coil 20, and improving the cooling effect of the coil 20.

In some embodiments, the coil groove 31 may be filled with the cooling conductive gel, and the cooling conductive gel may be arranged at intervals along a length direction of the coil conductor 21, and the coil 20 and the cooling conductive structure 30 may be bonded and fixed via the cooling conductive gel.

It may be understood that the cooling conductive gel is configured to fasten the coil 20 to the cooling conductive structure 30, so as to increase fastness of fixation between the coil 20 and the cooling conductive structure 30. The cooling conductive gel may be arranged at intervals along the length direction of the coil conductor 21, so as to ensure fastness of the coil 20, reduce an amount of the cooling conductive gel as much as possible, and reduce production costs.

Alternatively, a distance between adjacent fixed points of the cooling conductive gel may be less than or equal to 5 mm along a length direction of the coil 20.

In some embodiments, when the coil conductor 21 is mounted in the coil groove 31, the cooling conductive gel may be filled in the coil groove 31 first, the coil conductor 21 may be clamped into the coil groove 31, and then the cooling conductive gel may be filled again.

In some embodiments, a thermal conductivity of the cooling conductive grease and/or the cooling conductive gel may be greater than or equal to 1 w/(m·k).

It may be understood that, to reduce loss of the cooling of the cooling conductive structure 30 in a process of passing through the cooling conductive grease and/or the cooling conductive gel, the cooling conductive grease and/or the cooling conductive gel needs to be improved as much as possible. By calculation, simulation, and test verification, when the thermal conductivity of the the cooling conductive grease and/or the cooling conductive gel is greater than or equal to 1 w/(m·k), heat conducting efficiency and the production cost may be balanced, i.e., the cooling conductive grease and/or the cooling conductive gel may have a relatively low cost while ensuring that the coil 20 has relatively high cooling efficiency.

Referring to FIG. 2 and FIG. 3, in some embodiments, a surface defined by the coil 20 may be parallel to a surface of the cooling conductive structure 30 that is proximal to the to-be-tested target. In other words, the coil 20 and the cooling conductive structure 30 may be shaped to the side surface B of the cooling conductive structure 30 that is proximal to the to-be-tested target, so that the coil 20 may be accommodated in the coil groove 31, and the coil 20 may be tightly bonded to the inner wall C of the coil groove 31.

In addition, both the cooling conductive structure 30 and the housing 10 may be generally arc-shaped. In this way, it facilitates increasing a coverage range of the cryogenic probe on the to-be-tested target, so as to perform nuclear magnetic resonance imaging on different parts of the to-be-tested target.

Certainly, the coil 20, the cooling conductive structure 30, and the housing 10 may change a shape thereof according to a practical requirement. For example, a cross-sectional shape of the coil 20 may be a rectangle, and both the cooling conductive structure 30 and the housing 10 may be rectangular cubes, as long as the surface defined by the coil 20 is parallel to the side surface B of the cooling conductive structure 30 that is proximal to the to-be-tested target, which is not limited herein in the present disclosure.

In a second aspect of the present disclosure, a magnetic resonance imaging system is provided, including a magnetic resonance device (referring to FIG. 7) and the above cryogenic probe. The magnetic resonance device includes a magnet 41 with a scanning cavity 42, and the cryogenic probe is capable of partially entering the scanning cavity 42. The magnetic resonance imaging system is configured for pre-clinical and scientific research applications. Furthermore, the magnetic resonance imaging system is configured for animal imaging. The animal may be a mouse, such as an experimental mouse.

The various technical features of the above-described embodiments may be combined arbitrarily, and all possible combinations of the various technical features of the above-described embodiments have not been described for the sake of conciseness of description. However, as long as there is no contradiction in the combinations of these technical features, they should be considered to be within the scope of the present specification.

The above-described embodiments express only several embodiments of the present disclosure, which are described in a more specific and detailed manner, but are not to be construed as a limitation on the scope of the present disclosure. For one skilled in the art, several deformations and improvements can be made without departing from the conception of the present disclosure, all of which fall within the scope of protection of the present disclosure. Therefore, the scope of protection of the present disclosure shall be subject to the attached claims.

What is claimed is:

1. A cryogenic probe, comprising a housing, at least one coil, and a cooling conductive structure,
wherein the at least one coil is disposed in the housing; and
the cooling conductive structure is disposed in the housing and is provided with at least one coil groove, and the at least one coil is at least partially accommodated in the at least one coil groove.

2. The cryogenic probe of claim 1, wherein the at least one the coil groove is disposed on a side surface of the cooling conductive structure proximal to a to-be-tested target; and
any of the at least one coil comprises a coil conductor and a radio frequency element, the coil conductor is at least partially accommodated in one of the at least one coil groove, a gap exists between the cooling conductive structure and an inner wall of the housing, and a gap exists between the coil conductor and the inner wall of the housing.

3. The cryogenic probe of claim 2, wherein the side surface of the cooling conductive structure proximal to the to-be-tested target is an arc surface, and the coil conductor is at least partially accommodated in the one of the at least one coil groove along a radial direction of the arc surface.

4. The cryogenic probe of claim 3, wherein the coil conductor protrudes at least in part from the arc surface along the radial direction of the arc surface.

5. The cryogenic probe of claim 4, wherein a depth of the at least one coil groove is less than or equal to a size of the coil conductor along a depth direction of the at least one coil groove.

6. The cryogenic probe of claim 3, wherein an interior of the housing is a vacuum environment, and a gap between the coil conductor and the inner wall of the housing proximal to the to-be-tested target is less than or equal to 1.0 mm.

7. The cryogenic probe of claim 2, wherein the cooling conductive structure is further provided with a through hole in communication with the at least one coil groove, and the coil conductor is electrically connected to the radio frequency element through the through hole.

8. The cryogenic probe of claim 2, wherein the cryogenic probe comprises at least two coils, parts of adjacent coil conductors overlap with each other, and one of the adjacent coil conductors at an overlapping position prevents collisions with the other coil conductor of the adjacent coil conductors on a side away from the to-be-tested target.

9. The cryogenic probe of claim 2, wherein the at least one coil groove is filled with either or both of cooling conductive grease and cooling conductive gel, and either or both of cooling conductive grease and cooling conductive gel are in contact with both the coil conductor and an inner wall of the at least one coil groove.

10. The cryogenic probe of claim 2, wherein the at least one coil groove is filled with cooling conductive gel, and the cooling conductive gel is arranged at intervals along an extension direction of the coil conductor.

11. The cryogenic probe of claim 1, further comprising a cryogenic platform, wherein the cooling conductive structure is capable of performing heat exchange with the cryogenic platform.

12. A magnetic resonance imaging system, comprising a cryogenic probe and a magnetic resonance device, wherein the magnetic resonance device comprises a magnet with a scanning cavity, and the cryogenic probe is capable of partially entering the scanning cavity; and
the cryogenic probe comprises a housing, at least one coil, and a cooling conductive structure, wherein the at least one coil is disposed in the housing, the cooling conductive structure is disposed in the housing and is provided with at least one coil groove, and the at least one coil is at least partially accommodated in the at least one coil groove.

13. The magnetic resonance imaging system of claim 12, wherein the at least one coil groove is disposed on a side surface of the cooling conductive structure proximal to a to-be-tested target; and
any of the at least one coil comprises a coil conductor and a radio frequency element, the coil conductor is at least partially accommodated in one of the at least one coil groove, and a gap exists between the cooling conductive structure and an inner wall of the housing, and a gap exists between the coil conductor and the inner wall of the housing.

14. The magnetic resonance imaging system of claim 13, wherein the side surface of the cooling conductive structure proximal to the to-be-tested target is a circular arc surface, and the coil conductor is at least partially accommodated in the one of the at least one coil groove along a radial direction of the circular arc surface.

15. The magnetic resonance imaging system of claim 14, wherein the coil conductor protrudes at least in part from the arc surface along the radial direction of the arc surface.

16. The magnetic resonance imaging system of claim 15, wherein a depth of the at least one coil groove is less than or equal to a size of the coil conductor along a depth direction of the at least one coil groove.

17. The magnetic resonance imaging system of claim 14, wherein an interior of the housing is a vacuum environment, and a gap between the coil conductor and the inner wall of the housing proximal to the to-be-tested target is less than or equal to 1.0 mm.

18. The magnetic resonance imaging system of claim 13, wherein the cooling conductive structure is further provided with a through hole in communication with the at least one coil groove, and the coil conductor is electrically connected to the radio frequency element through the through hole.

19. The magnetic resonance imaging system of claim 13, wherein the cryogenic probe comprises at least two coils, parts of adjacent coil conductors overlap with each other, and one of the adjacent coil conductors at an overlapping position prevents collisions with the other coil conductor of the adjacent coil conductors on a side away from the to-be-tested target.

20. The magnetic resonance imaging system of claim 13, wherein the at least one coil groove is filled with either or both of cooling conductive grease and cooling conductive gel, and either or both of cooling conductive grease and cooling conductive gel are in contact with both the coil conductor and an inner wall of the at least one coil groove.
